(19) United States
(12) Patent Application Publication
(10) Pub. No.: US 2012/0043198 A1
(43) Pub. Date: Feb. 23, 2012

(54) FILM FORMATION APPARATUS AND FILM FORMATION METHOD

(75) Inventor: Shunpei YAMAZAKI, Setagaya (JP)

(73) Assignee: SEMICONDUCTOR ENERGY LABORATORY CO., LTD., Atsugi-shi (JP)

(21) Appl. No.: 13/204,810

(22) Filed: Aug. 8, 2011

(30) Foreign Application Priority Data
Aug. 18, 2010 (JP) 2010-183025
Apr. 5, 2011 (JP) 2011-083966

(51) Int. Cl. C23C 14/08; C23C 14/34; C23C 16/458

(52) U.S. Cl. 204/192.1; 118/719; 204/298.09

(57) ABSTRACT

There have been cases where transistors using oxide semiconductors are inferior in reliability to transistors using amorphous silicon. There have also been cases where transistors using oxide semiconductors show great variation in electrical characteristics within one substrate, from substrate to substrate, or from lot to lot. Therefore, an object is to manufacture a semiconductor device using an oxide semiconductor which has high reliability and less variation in electrical characteristics. Provided is a film formation apparatus including a load lock chamber, a transfer chamber connected to the load lock chamber through a gate valve, a substrate heating chamber connected to the transfer chamber through a gate valve, and a film formation chamber having a leakage rate less than or equal to 1×10⁻¹⁰ Pa·m³/sec, which is connected to the transfer chamber through a gate valve.

### BACKGROUND OF THE INVENTION

1. Field of the Invention

The present invention relates to a film formation apparatus and a film formation method.

Note that in this specification, a semiconductor device refers to any device that can function by utilizing semiconductor characteristics, and an electro-optical device, a semiconductor circuit, and an electronic device are all semiconductor devices.

2. Description of the Related Art

A technique by which transistors are formed using semiconductor thin films formed over a substrate having an insulating surface has been attracting attention. Such transistors are applied to a wide range of electronic devices, such as integrated circuits (IC) and image display devices (display devices). As materials of semiconductor thin films applicable to the transistors, silicon-based semiconductor materials have been widely used, but oxide semiconductors have been attracting attention as alternative materials.

For example, disclosure is made of a transistor having an active layer for which an oxide semiconductor that contains indium (In), gallium (Ga) and zinc (Zn) and has an electron carrier concentration less than 10¹⁸/cm³ is used, and a sputtering method is considered the most suitable as a method of forming a film of the oxide semiconductor (see Patent Document 1).

### REFERENCE

Patent Document 1: Japanese Published Patent Application No. 2006-165528

### SUMMARY OF THE INVENTION

There have been cases where transistors using oxide semiconductors are inferior in reliability to transistors using amorphous silicon. There have also been cases where transistors using oxide semiconductors show great variation in electrical characteristics within one substrate, from substrate to substrate, or from lot to lot. Therefore, an object is to manufacture a semiconductor device using an oxide semiconductor which has high reliability and less variation in electrical characteristics, and a film formation apparatus therefor and a film formation method using the film formation apparatus will be described.

It is known that in a transistor using an oxide semiconductor, part of hydrogen serves as a donor to generate an electron. The generation of an electron in an oxide semiconductor causes drain current to flow even without application of a gate voltage, and accordingly, the threshold voltage shifts in the negative direction. A transistor using an oxide semiconductor is likely to have n-type conductivity, and it comes to have normally-on characteristics by a shift of threshold voltage in the negative direction. “Normally on” here refers to the state where a channel exists without application of a voltage to a gate electrode and a current flows through a transistor.

Furthermore, the threshold voltage of a transistor might vary due to entry of hydrogen into the oxide semiconductor after fabrication of the transistor. A shift of threshold voltage significantly impairs the reliability of the transistor.

The present inventor has found that film formation by a sputtering method causes unintended inclusion of hydrogen in a film. Note that in this specification, “hydrogen” refers to a hydrogen atom, and, for example, includes hydrogen contained in a hydrogen molecule, hydrocarbon, hydroxyl, water, and the like in the expression “including hydrogen”.

One embodiment of the present invention is a film formation apparatus including a load lock chamber, a transfer chamber connected to the load lock chamber through a gate valve, a substrate heating chamber connected to the transfer chamber through a gate valve, and a film formation chamber having a leakage rate less than or equal to 1×10⁻¹⁰ Pa·m³/sec, which is connected to the transfer chamber through a gate valve.

Note that more than one load lock chamber, more than one substrate heating chamber, or more than one film formation chamber may be included.

Another embodiment of the present invention is a film formation apparatus including a load lock chamber, a substrate heating chamber connected to the load lock chamber through a gate valve, and a film formation chamber having a leakage rate less than or equal to 1×10⁻¹⁰ Pa·m³/sec, which is connected to the substrate heating chamber through a gate valve.

Still another embodiment of the present invention is a film formation apparatus including a load lock chamber, a substrate heating chamber connected to the load lock chamber through a gate valve, a first film formation chamber having a leakage rate less than or equal to 1×10⁻¹⁰ Pa·m³/sec, which is connected to the substrate heating chamber through a gate valve, and a second film formation chamber having a leakage rate less than or equal to 1×10⁻¹⁰ Pa·m³/sec, which is connected to the first film formation chamber through a gate valve.

Here, the purity of a film formation gas is preferably greater than or equal to 99.999999%. In order to increase the purity of the film formation gas, a gas refiner may be provided between a source of the film formation gas and the film formation chamber. The length of a pipe between the gas refiner and the film formation chamber is less than or equal to 5 m, preferably less than or equal to 1 m.

One embodiment of the present invention is a film formation apparatus in which a film formation pressure is controlled to be less than or equal to 0.8 Pa, preferably less than or equal to 0.4 Pa, and a distance between a target and a substrate during film formation is less than or equal to 40 mm, preferably less than or equal to 25 mm.

One embodiment of the present invention is a film formation method, in which a film formation gas having a purity greater than or equal to 99.999999% is introduced into a film formation chamber having a leakage rate less than or equal to 1×10⁻¹⁰ Pa·m³/sec which is evacuated to a vacuum level, after a substrate is introduced into the film formation chamber, and a target is sputtered using the film formation gas to form a film over the substrate.

Another embodiment of the present invention is a film formation method, in which a substrate is subjected to heat treatment at a temperature greater than or equal to 250° C. and less than the strain point of the substrate in an inert atmosphere, a reduced-pressure atmosphere, or a dry air atmosphere after the substrate is introduced into a substrate heating chamber evacuated to a vacuum level, a film formation gas having a purity greater than or equal to 99.999999% is introduced into a film formation chamber after the substrate subjected to the heat treatment is introduced into the film formation chamber having a leakage rate less than or equal to 1×10⁻¹⁰ Pa·m³/sec which is evacuated to a vacuum level without exposure to air, and a target is sputtered using the film formation gas to form a film over the substrate.

In this specification, the reduced-pressure atmosphere refers to a pressure of 10 Pa or less. Further, the inert atmosphere refers to an atmosphere containing an inert gas (such as nitrogen or a rare gas (e.g., helium, neon, argon, krypton, or xenon)) as the main component, and preferably contains no hydrogen. For example, the purity of the inert gas to be introduced is 8N (99.999999%) or more, preferably 9N (99.9999999%) or more. Alternatively, the inert atmosphere refers to an atmosphere that contains an inert gas as the main component and contains a reactive gas at a concentration less than 0.1 ppm. The reactive gas refers to a gas that reacts with a semiconductor, metal, or the like.

Another embodiment of the present invention is a film formation method, in which a substrate is subjected to heat treatment at a temperature greater than or equal to 250° C. and less than the strain point of the substrate in an inert atmosphere, a reduced-pressure atmosphere, or a dry air atmosphere after the substrate is introduced into a substrate heating chamber evacuated to a vacuum level, a film formation gas having a purity greater than or equal to 99.999999% is introduced into a first film formation chamber after the substrate subjected to the heat treatment is introduced into the first film formation chamber having a leakage rate less than or equal to 1×10⁻¹⁰ Pa·m³/sec which is evacuated to a vacuum level without exposure to air, a target is sputtered using the film formation gas to form an insulating film over the substrate, a film formation gas having a purity greater than or equal to 99.999999% is introduced into a second film formation chamber after the substrate provided with the insulating film is introduced into the second film formation chamber having a leakage rate less than or equal to 1×10⁻¹⁰ Pa·m³/sec which is evacuated to a vacuum level without exposure to air, and a target is sputtered using the film formation gas to form an oxide semiconductor film over the substrate.

Here, the insulating film is preferably formed with a substrate temperature greater than or equal to 50° C. and less than or equal to 450° C. With the substrate temperature greater than or equal to 50° C. and less than or equal to 450° C., hydrogen contained in the insulating film can be reduced. More preferably, the substrate temperature is greater than or equal to 100° C. and less than or equal to 400° C.

In addition, the oxide semiconductor film is preferably formed with a substrate temperature greater than or equal to 100° C. and less than or equal to 400° C.

Note that in the case where the substrate heating chamber also serves as a plasma treatment chamber, hydrogen on a substrate surface may be reduced through plasma treatment instead of the above-mentioned heat treatment. The plasma treatment enables treatment at low temperature and efficient removal of hydrogen in a short time, and is particularly effective in removing hydrogen which is strongly bonded to a substrate surface.

Further, entry of hydrogen from the outside can be suppressed by films between which a transistor is interposed and which block hydrogen. Furthermore, there is need to reduce the effect of desorption and diffusion of hydrogen from a film included in a transistor; for that, a reduction of the hydrogen concentration in the film included in the transistor is effective. In addition, an interface between films might contain hydrogen adsorbed in air; in order to reduce such hydrogen, maximum avoidance of exposure to air is effective. If the exposure to air cannot, however, be avoided, heat treatment is preferably conducted just before film formation at a temperature greater than or equal to 250° C. and less than the strain point of the substrate in an inert atmosphere, a reduced-pressure atmosphere, or a dry air atmosphere. Through this heat treatment, adsorbed hydrogen on a substrate surface can be removed efficiently.

As described above, a technical idea of one embodiment of the present invention is to reduce hydrogen entering into each film or at an interface of films included in a transistor.

According to one embodiment of the present invention, hydrogen contained in an oxide semiconductor film can be reduced, and a transistor having stable electrical characteristics with less variation in threshold voltage can be provided.

Alternatively, according to one embodiment of the present invention, hydrogen in a film in contact with an oxide semiconductor film can be reduced, and accordingly, entry of hydrogen into the oxide semiconductor film can be suppressed. Thus, a semiconductor device having a transistor with good electrical characteristics and high reliability can be provided.

### BRIEF DESCRIPTION OF THE DRAWINGS

FIGS. 1A and 1B are top views each illustrating an example of a film formation apparatus which is one embodiment of the present invention.

FIGS. 2A and 2B illustrate a film formation apparatus which is one embodiment of the present invention.

FIGS. 3A to 3C are a top view and cross-sectional views illustrating an example of a semiconductor device which is one embodiment of the present invention.

FIGS. 4A and 4B are cross-sectional views each illustrating an example of a semiconductor device which is one embodiment of the present invention.

FIGS. 5A to 5C are cross-sectional views each illustrating an example of a semiconductor device which is one embodiment of the present invention.

FIGS. 6A to 6E are cross-sectional views illustrating an example of a manufacturing process of a semiconductor device which is one embodiment of the present invention.

FIGS. 7A to 7E are cross-sectional views illustrating an example of a manufacturing process of a semiconductor device which is one embodiment of the present invention.

FIGS. 8A to 8C are cross-sectional views illustrating an example of a manufacturing process of a semiconductor device which is one embodiment of the present invention.

FIGS. 9A and 9B show the measurement results of the hydrogen concentrations by SIMS.

FIGS. 10A to 10F each show TDS spectra when the value of m/z was 18.

### DETAILED DESCRIPTION OF THE INVENTION

Hereinafter, embodiments of the present invention will be described in detail with reference to the accompanying drawings. However, the present invention is not limited to the description below and it is easily understood by those skilled in the art that the mode and details can be modified in various ways. Further, the present invention is not construed as being limited to the description of the embodiments given below. Note that in the description of the present invention with reference to the drawings, components common between different drawings maintain the same reference numerals. Note also that the same hatching pattern is applied to similar parts, and the similar parts are not especially denoted by reference numerals in some cases.

Note that the ordinal numbers such as “first” and “second” in this specification are used for convenience and do not indicate the order of steps or the stacking order of layers. In addition, the ordinal numbers in this specification do not denote particular names which specify the present invention.

### Embodiment 1

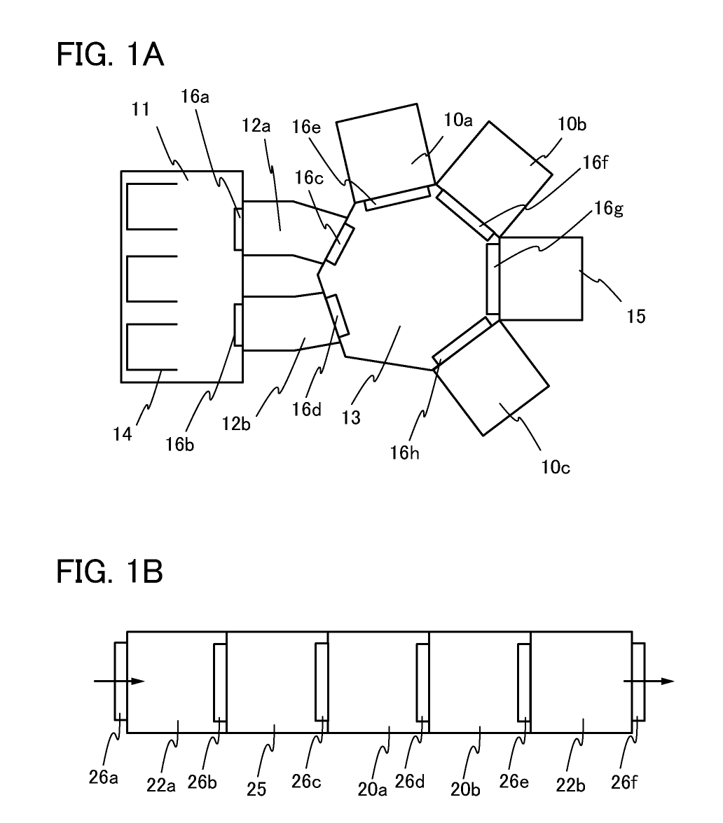

In this embodiment, a structure of a film formation apparatus with less entry of hydrogen during film formation will be described using FIGS. 1A and 1B.

FIG. 1A illustrates a multi-chamber film formation apparatus. The film formation apparatus includes a substrate supply chamber 11 having three cassette ports 14 accommodating a substrate, a load lock chamber 12a, a load lock chamber 12b, a transfer chamber 13, a substrate heating chamber 15, a film formation chamber 10a with a leakage rate less than or equal to 1×10⁻¹⁰ Pa·m³/sec, a film formation chamber 10b with a leakage rate less than or equal to 1×10⁻¹⁰ Pa·m³/sec, and a film formation chamber 10c with a leakage rate less than or equal to 1×10⁻¹⁰ Pa·m³/sec. The substrate supply chamber is connected to the load lock chamber 12a and the load lock chamber 12b. The load lock chamber 12a and the load lock chamber 12b are connected to the transfer chamber 13. The substrate heating chamber 15 and the film formation chambers 10a to 10c are each connected only to the transfer chamber 13. Gate valves 16a to 16h are provided for connecting portions of chambers so that each chamber can be independently kept in a vacuum state. Note that a film formation gas having a purity greater than or equal to 99.999999% can be introduced into the film formation chambers 10a to 10c. Although not illustrated, the transfer chamber 13 has one or more substrate transfer robots. Here, the atmosphere in the substrate heating chamber 15 can be controlled to be the one containing almost no hydrogen (e.g., an inert atmosphere, a reduced-pressure atmosphere, or a dry air atmosphere); for example, a dry nitrogen atmosphere having a dew point of −40° C. or less, preferably −50° C. or less, is possible in terms of moisture. Here, the substrate heating chamber 15 preferably also serves as a plasma treatment chamber. With a single wafer multi-chamber film formation apparatus, a substrate does not need to be exposed to air between treatments, and adsorption of hydrogen to a substrate can be suppressed. In addition, the order of film formation, heat treatment, or the like can be freely created. Note that the numbers of the film formation chambers, the load lock chambers and the substrate heating chambers are not limited to the above numbers, and can be determined as appropriate depending on the space for placement or the process.

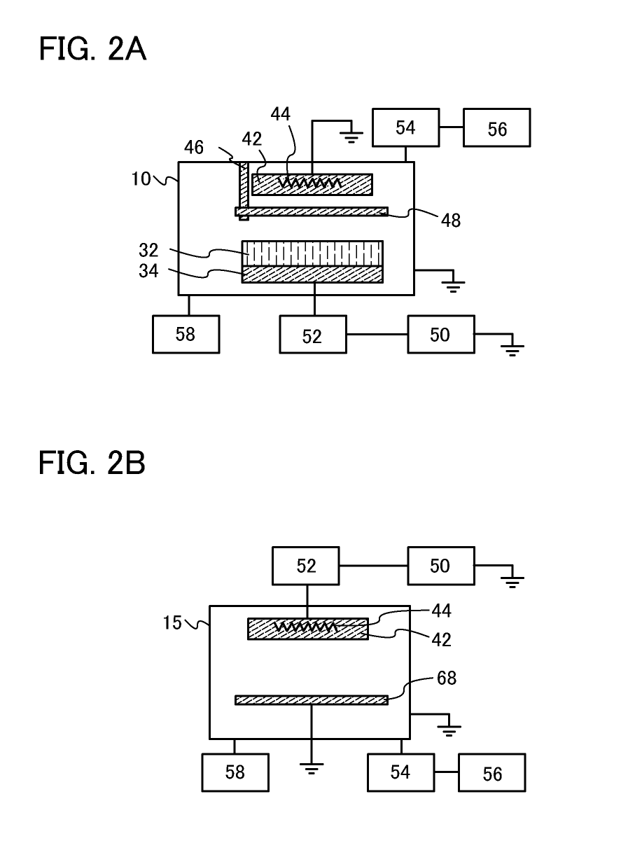

An example of the film formation chamber illustrated in FIG. 1A will be described using FIG. 2A. The film formation chamber 10 includes a target 32, a target holder 34 supporting a target, an RF power source 50 supplying electric power to a target holder 34 through a matching box 52, a substrate holder 42 which holds a substrate and in which a substrate heater 44 is embedded, a shutter plate 48 which can rotate around a shutter axis 46 as the axis, a film formation gas source 56 supplying a film formation gas, a gas refiner 54 provided between the film formation gas source 56 and the film formation chamber 10, and a vacuum pump 58 connected to the film formation chamber 10. Here, the film formation chamber 10, the RF power source 50, the shutter axis 46, the shutter plate 48, and the substrate holder 42 are connected to GND. However, one or more of the film formation chamber 10, the shutter axis 46, the shutter plate 48, and the substrate holder 42 may be electrically floating depending on the purpose. Further, the vacuum pump 58 is not limited to one pump, and more than one pump may be provided; for example, a rough vacuum pump and a high vacuum pump can be connected in parallel or in series. Further, more than one set of film formation gas source 56 and gas refiner 54 may be provided; for example, depending on the number of the film formation gases, sets of the film formation gas source and the gas refiner can be added. The additional set of the film formation gas source and the gas refiner may be directly connected to the film formation chamber 10, and in that case, a mass flow controller for controlling the flow rate of the film formation gas may be provided between each gas refiner and the film formation chamber 10. Alternatively, the additional set of the film formation gas source and the gas refiner may be connected to a pipe connecting the film formation chamber 10 and the gas refiner 54 to each other. Although not illustrated, a magnet is preferably provided inside or on the bottom portion of the target holder 34, so that high-density plasma can be confined in the vicinity of the target. This method is called a magnetron sputtering method, in which the deposition rate is high, less plasma damage is done to a substrate, and film qualities are made good. In the magnetron sputtering method, the rotatability of a magnet can reduce a bias in a magnetic field, so that efficiency in the use of the target is increased and variation in film qualities on a substrate surface can be reduced. Furthermore, although the RF power source is here used as a power source for sputtering, it is not necessarily limited to the RF power source and may be replaced with a DC power source or an AC power source depending on the uses, or two or more types of power sources may be provided and switched. Use of a DC power source or an AC power source eliminates the need for the matching box between the power source and the target holder. Moreover, the substrate holder needs to be provided with a chuck mechanism for supporting a substrate; as the chuck mechanism, an electrostatic chuck system, a clamping system, and the like can be given. The substrate holder may be provided with a rotation mechanism in order to improve the uniformity of film qualities and the thickness on a substrate surface. More than one substrate holder may be provided so that the film formation chamber is capable of film formation for more than one substrate at one time. In addition, a structure in which the shutter axis 46, the shutter plate 48, and the substrate heater 44 are not provided may be used. Although FIG. 2A illustrates a structure in which the target is below the substrate, a structure in which the target is above or beside the substrate may be used.

In the substrate heating chamber 15, for example, a resistance heater or the like may be used for heating. Alternatively, a substrate may be heated by heat conduction or heat radiation from a medium such as a heated gas. For example, RTA (rapid thermal anneal) treatment, such as GRTA (gas rapid thermal anneal) treatment or LRTA (lamp rapid thermal anneal) treatment, can be used. The LRTA treatment is treatment for heating an object by radiation of light (an electromagnetic wave) emitted from a lamp, such as a halogen lamp, a metal halide lamp, a xenon arc lamp, a carbon arc lamp, a high-pressure sodium lamp, or a high-pressure mercury lamp. The GRTA treatment is treatment for performing a heat treatment using a high-temperature gas; an inert gas is used as the gas.

For example, the substrate heating chamber 15 can have a structure illustrated in FIG. 2B. The substrate heating chamber 15 has the substrate holder 42 in which the substrate heater 44 is embedded, the film formation gas source 56 which supplies the film formation gas, the gas refiner 54 provided between the film formation gas source 56 and the substrate heating chamber 15, and a vacuum pump 58 connected to the substrate heating chamber 15. Here, in the case where the substrate heating chamber 15 also serves as a plasma treatment chamber, the substrate holder 42 is connected to the RF power source 50 through the matching box 52, and a counter electrode 68 is provided. Note that instead of a heating mechanism of the substrate heater, an LRTA apparatus may be provided on the position opposite to the substrate holder; in that case, the substrate holder 42 may be provided with a reflective plate in order that heat be efficiently conducted to the substrate.

FIG. 1B illustrates a film formation apparatus that differs in structure from the film formation apparatus in FIG. 1A, and includes a load lock chamber 22a, a substrate heating chamber 25, a film formation chamber 20a with a leakage rate less than or equal to 1×10⁻¹⁰ Pa·m³/sec, a film formation chamber 20b with a leakage rate less than or equal to 1×10⁻¹⁰ Pa·m³/sec, and a load lock chamber 22b. The load lock chamber 22a is connected to the substrate heating chamber 25; the substrate heating chamber 25 is connected to the film formation chamber 20a; the film formation chamber 20a is connected to the film formation chamber 20b; and the film formation chamber 20b is connected to the load lock chamber 22b. Gate valves 26a to 26f are provided for connecting portions of chambers so that each chamber can be independently kept in a vacuum state. Note that the film formation chambers 20a and 20b each have the same structure as the film formation chambers 10a to 10c in FIG. 1A. Further, the substrate heating chamber 25 has the same structure as the substrate heating chamber 15 in FIG. 1A. A substrate is transferred in only one direction indicated by arrows in FIG. 1B, and the inlet and outlet for the substrate are different. Unlike the single wafer multi-chamber film formation apparatus in FIG. 1A, there is no transfer chamber, and the footprint can be reduced accordingly. Note that the numbers of the film formation chambers, the load lock chambers and the substrate heating chambers are not limited to the above numbers, and can be determined as appropriate depending on the space for placement or the process. For example, the film formation chamber 20b may be omitted, or a second or third film formation chamber connected to the film formation chamber 20b may be provided.

In film formation at room temperature, the amount of hydrogen entering into a film is estimated to be 10² to 10⁴ times as large as that of hydrogen in the film formation chamber. For that reason, hydrogen in the film formation chamber needs to be reduced as much as possible.

Specifically, with a leakage rate of the film formation chamber less than or equal to 1×10⁻¹⁰ Pa·m³/sec, the hydrogen entering into a film in the film formation can be reduced.

The leakage is broadly classified into external leakage and internal leakage. The external leakage refers to inflow of gas from the outside of a vacuum system through a minute hole, a sealing defect, or the like. The internal leakage is due to leakage through a partition, such as a valve, in a vacuum system or due to released gas from an internal member. Measures need to be taken from both aspects of external leakage and internal leakage in order that the leakage rate be less than or equal to 1×10⁻¹⁰ Pa·m³/sec.

For example, an open/close portion of the film formation chamber is preferably sealed with a metal gasket. For the metal gasket, a metal material covered with iron fluoride, aluminum oxide, or chromium oxide is preferably used. The metal gasket realizes higher adhesion than an O-ring, and can reduce the external leakage. Further, by use of a metal material covered with iron fluoride, aluminum oxide, chromium oxide, or the like which is in the passive state, released gas containing hydrogen generated from the metal gasket is suppressed, so that the internal leakage can be reduced.

As a member forming the film formation apparatus, aluminum, chromium, titanium, zirconium, nickel, or vanadium, from which the released gas containing hydrogen is in a smaller amount, is used. An alloy material containing iron, chromium, nickel, and the like covered with the above-mentioned material may be used. The alloy material containing iron, chromium, nickel, and the like is resistant to heat and suitable for processing. Here, when surface unevenness of the member is decreased by polishing or the like to reduce the surface area, the released gas can be reduced.

Alternatively, the above-mentioned member of the film formation apparatus may be covered with iron fluoride, aluminum oxide, chromium oxide, or the like.

The member of the film formation apparatus is preferably formed with only a metal material as much as possible. For example, in the case where a viewing window formed with quartz or the like is provided, a surface is preferably covered thinly with iron fluoride, aluminum oxide, chromium oxide, or the like so as to suppress the released gas.

Further, the film formation pressure is less than or equal to 0.8 Pa, preferably less than or equal to 0.4 Pa, and the distance between a target and a substrate during film formation is less than or equal to 40 mm, preferably less than or equal to 25 mm, so that the frequency of the collision of a sputtered particle and another sputtered particle, a gas molecule, or an ion can be reduced. That is, depending on the film formation pressure, the distance between a target and a substrate should be made shorter than the mean free path of a sputtered particle, a gas molecule, or an ion. For example, when the pressure is 0.4 Pa and the temperature is 25° C. (the absolute temperature is 298K), an argon molecule has a mean free path of 28.3 mm, an oxygen molecule has a mean free path of 26.4 mm, a hydrogen molecule has a mean free path of 48.7 mm, a water molecule has a mean free path of 31.3 mm, a helium molecule has a mean free path of 57.9 mm, and a neon molecule has a mean free path of 42.3 mm. Note that doubling of the pressure halves a mean free path and doubling of the absolute temperature doubles a mean free path.

Here, the gas refiner may be provided just in front of the film formation gas is introduced. At this time, the length of a pipe between the gas refiner and the film formation chamber is less than or equal to 5 m, preferably less than or equal to 1 m. When the length of the pipe is less than or equal to 5 m or less than or equal to 1 m, the effect of the released gas from the pipe can be reduced accordingly.

Furthermore, as the pipe for the film formation gas, a metal pipe the inside of which is covered with iron fluoride, aluminum oxide, chromium oxide, or the like is preferably used. With the above-mentioned pipe, the amount of released gas containing hydrogen is small and entry of impurities into the film formation gas can be reduced as compared with a SUS316L-EP pipe, for example. Further, a high-performance ultra-compact metal gasket joint (a UPG joint) is preferably used as a joint of the pipe. In addition, a structure where all the materials of the pipe are metal materials is preferable, in which the effect of the generated released gas or the external leakage can be reduced as compared to a structure where resin or the like is used.

Evacuation of the film formation chamber is preferably performed with a rough vacuum pump, such as a dry pump, and a high vacuum pump, such as a sputter ion pump, a turbo molecular pump or a cryopump, in appropriate combination. The turbo molecular pump has an outstanding capability in evacuating a large-sized molecule, whereas it has a low capability in evacuating hydrogen or water. Hence, combination of a cryopump having a high capability in evacuating water and a sputter ion pump having a high capability in evacuating hydrogen is effective.

Because it is adsorbed, an adsorbate present in the film formation chamber does not affect the pressure in the film formation chamber, but the adsorbate leads to release of gas at the time of the evacuation of the film formation chamber. Therefore, although the leakage rate and the evacuation rate do not have a correlation, it is important that the adsorbate present in the film formation chamber be desorbed as much as possible and evacuation be performed in advance with use of a pump having high evacuation capability. Note that the film formation chamber may be subjected to baking for promotion of desorption of the adsorbate. By the baking, the rate of desorption of the adsorbate can be increased about tenfold. The baking should be performed at a temperature greater than or equal to 100° C. and less than or equal to 450° C. At this time, when the adsorbate is removed while an inert gas is introduced, the rate of desorption of water or the like, which is difficult to desorb only by evacuation, can be further increased. Note that the rate of desorption of the adsorbate can be further increased by heating of the inert gas to be introduced at substantially the same temperature as the temperature of the baking. In addition, the rate of desorption of the adsorbate can be further increased also by dummy film formation performed at the same time as the baking. Here, the dummy film formation refers to film formation on a dummy substrate by sputtering, in which a film is deposited on the dummy substrate and the inner wall of a film formation chamber so that impurities in the film formation chamber and an adsorbate on the inner wall of the film formation chamber are confined in the film. For the dummy substrate, a material from which the released gas is in a smaller amount is preferably used, and for example, the same material as that of the substrate 100 may be used.

Hydrogen entry into an oxide semiconductor film can be suppressed by use of the above-described film formation apparatus for formation of the oxide semiconductor film. Furthermore, hydrogen entry into the oxide semiconductor film from a film in contact therewith can be suppressed by use of the above-described film formation apparatus for formation of the film in contact with the oxide semiconductor film. Consequently, a semiconductor device with high reliability and less variation in electrical characteristics can be manufactured.

### Embodiment 2

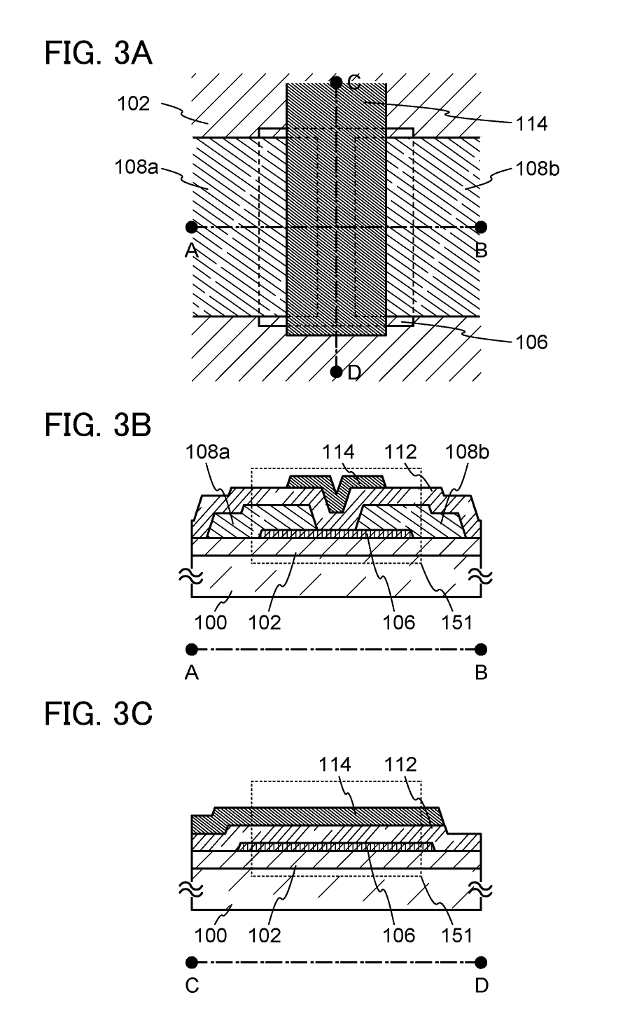

In this embodiment, one mode of a method of manufacturing a semiconductor device using a film formation method with less entry of hydrogen will be described with reference to FIGS. 3A to 3C, FIGS. 4A and 4B, FIGS. 5A to 5C, FIGS. 6A to 6E, and FIGS. 7A to 7E.

In FIGS. 3A to 3C, a top view and cross-sectional views of a transistor 151 which is a top-gate top-contact type is illustrated as an example of a semiconductor device according to one embodiment of the present invention. Here, FIG. 3A is a top view, FIG. 3B is a cross-sectional view along A-B in FIG. 3A, and FIG. 3C is a cross-sectional view along C-D in FIG. 3A. Note that in FIG. 3A, some of the components of the thin film transistor 151 (e.g., a gate insulating film 112) are omitted for brevity.

The transistor 151 in FIGS. 3A to 3C includes a substrate 100, an insulating film 102 over the substrate 100, an oxide semiconductor film 106 over the insulating film 102, a source electrode 108a and a drain electrode 108b provided over the oxide semiconductor film 106, a gate insulating film 112 which covers the source electrode 108a and the drain electrode 108b and part of which is in contact with the oxide semiconductor film 106, and a gate electrode 114 provided over the oxide semiconductor film 106 with the gate insulating film 112 interposed therebetween.

At least enough heat resistance to withstand later-performed heat treatment is necessary, although there is no particular limitation on the properties of a material and the like of the substrate 100. As the substrate 100, for example, a glass substrate, a ceramic substrate, a quartz substrate, a sapphire substrate, or the like can be used. Any of the following substrates can also be used: a single crystal semiconductor substrate or a polycrystalline semiconductor substrate made of silicon, silicon carbide, or the like; a compound semiconductor substrate made of silicon germanium or the like; an SOI substrate; and the like. Any of these substrates further provided with a semiconductor element may be used as the substrate 100.

As the substrate 100, a flexible substrate may be used. In that case, a transistor may be formed directly on the flexible substrate. Note that to provide a transistor on the flexible substrate, there is also a method in which a transistor is formed over a non-flexible substrate, and the transistor is then separated and transferred to a flexible substrate which is the substrate 100. In that case, a separation is preferably provided between the substrate 100 and the transistor.

As a material of the insulating film 102, a single layer or a stack of silicon oxide, silicon oxynitride, silicon nitride, silicon nitride oxide, aluminum oxide, aluminum nitride, or the like is used. For example, the insulating film 102 has a stack structure of a silicon nitride film and a silicon oxide film, so that entry of moisture into the transistor 151 from the substrate or the like can be prevented. When the insulating film 102 has a stack structure, a film on the side in contact with the oxide semiconductor film 106 is preferably an insulating film that releases oxygen by heating (e.g., silicon oxide, silicon oxynitride, or aluminum oxide); accordingly, oxygen is supplied from the insulating film 102 to the oxide semiconductor film 106, and it is possible to reduce oxygen deficiency of the oxide semiconductor film 106 and the interface state density between the insulating film 102 and the oxide semiconductor film 106. The oxygen deficiency of the oxide semiconductor film 106 causes the threshold voltage to shift in the negative direction, and the interface state density between the insulating film 102 and the oxide semiconductor film 106 reduces the reliability of the transistor. Note that the insulating film 102 functions as a base film of the transistor 151.

Note that the silicon oxynitride here refers to a material having a composition in which the oxygen content is higher than the nitrogen content, preferably a material having the following composition ranges: 50 at. % to 70 at. % oxygen; 0.5 at. % to 15 at. % nitrogen; 25 at. % to 35 at. % silicon; and 0 at. % to 10 at. % hydrogen when they are measured by Rutherford backscattering spectrometry (RBS) and hydrogen forward scattering (HFS). Further, the silicon nitride oxide refers to a material having a composition in which the nitrogen content is higher than that the oxygen content, preferably a material having the following composition ranges: 5 at. % to 30 at. % oxygen; 20 at. % to 55 at. % nitrogen; 25 at. % to 35 at. % silicon; and 10 at. % to 30 at. % hydrogen when they are measured by RBS and HFS. Note that the percentages of nitrogen, oxygen, silicon, and hydrogen contents fall within the above ranges, when the total number of atoms contained in the silicon oxynitride or the silicon nitride oxide is 100 at. %.

The “insulating film that releases oxygen by heating” refers to an insulating film from which the amount of released oxygen is greater than or equal to 1.0×10¹⁸ atoms/cm³, preferably greater than or equal to 1.0×10²⁰ atoms/cm³, further preferably greater than or equal to 3.0×10²⁰ atoms/cm³ when converted into oxygen atoms by TDS (thermal desorption spectroscopy) analysis.

Here, a method in which the amount of released oxygen is measured by being converted into oxygen atoms using TDS analysis will now be described.

The amount of released gas in TDS analysis is proportional to the integral value of a spectrum. Therefore, the amount of released gas can be calculated from the ratio between the integral value of a spectrum of an insulating film and the reference value of a standard sample. The reference value of a standard sample refers to the ratio of the density of a predetermined atom contained in a sample to the integral value of a spectrum.

For example, the number of the released oxygen molecules (N_{O2}) from an insulating film can be found according to a numerical expression 1 with the TDS analysis results of a silicon wafer containing hydrogen at a predetermined density which is the standard sample and the TDS analysis results of the insulating film. Here, all spectra having a mass number of 32 which are obtained by the TDS analysis are assumed to originate from an oxygen molecule. CH₃OH, which is given as a gas having a mass number of 32, is not taken into consideration on the assumption that it is unlikely to be present. Further, an oxygen molecule including an oxygen atom having a mass number of 17 or 18 which is an isotope of an oxygen atom is also not taken into consideration because the proportion of such a molecule in the natural world is minimal.

N_{O2}=N_{H2}/S_{H2}×S_{O2}×α (numerical expression 1)

N_{H2} is the value obtained by conversion of the number of hydrogen molecules desorbed from the standard sample into densities. S_{H2} is the integral value of a spectrum when the standard sample is subjected to TDS analysis. Here, the reference value of the standard sample is set to N_{H2}/S_{H2}. S_{O2} is the integral value of a spectrum when the insulating film is subjected to TDS analysis. α is a coefficient affecting the intensity of the spectrum in the TDS analysis. Refer to Japanese Published Patent Application No. H6-275697 for details of the numerical expression 1. Note that the amount of released oxygen from the above insulating film is measured with a thermal desorption spectroscopy apparatus produced by ESCO Ltd., EMD-WA1000S/W using a silicon wafer containing a hydrogen atom at 1×10¹⁶ atoms/cm³ as the standard sample.

Further, in the TDS analysis, oxygen is partly detected as an oxygen atom. The ratio between oxygen molecules and oxygen atoms can be calculated from the ionization rate of the oxygen molecules. Note that, since the above a includes the ionization rate of the oxygen molecules, the number of the released oxygen atoms can also be estimated through the evaluation of the number of the released oxygen molecules.

Note that N_{O2} is the number of the released oxygen molecules. For the insulating film, the amount of released oxygen when converted into oxygen atoms is twice the number of the released oxygen molecules.

In the above structure, the insulating film that releases oxygen by heating may be oxygen-excess silicon oxide (SiO_{X} (X>2)). The oxygen-excess silicon oxide (SiO_{X} (X>2)) refers to a material in which the number of oxygen atoms is more than twice that of silicon atoms per unit volume. The number of silicon atoms and the number of oxygen atoms per unit volume are the values measured by Rutherford backscattering spectrometry.

As a material used for the oxide semiconductor film, any of the following materials may be used: an In—Sn—Ga—Zn—O-based material which is a metal oxide of four metal elements; an In—Ga—Zn—O-based material, an In—Sn—Zn—O-based material, an In—Al—Zn—O-based material, a Sn—Ga—Zn—O-based material, an Al—Ga—Zn—O-based material, and a Sn—Al—Zn—O-based material which are metal oxides of three metal elements; an In—Zn—O-based material, a Sn—Zn—O-based material, an Al—Zn—O-based material, a Zn—Mg—O-based material, a Sn—Mg—O-based material, and an In—Mg—O-based material, and an In—Ga—O-based material which are metal oxides of two metal elements; an In—O-based material; a Sn—O-based material; a Zn—O-based material; and the like. In addition, the above materials may each contain SiO₂. Here, for example, an In—Ga—Zn—O-based material means an oxide film containing indium (In), gallium (Ga), and zinc (Zn), and there is no particular limitation on the composition ratio. Further, the In—Ga—Zn—O-based oxide semiconductor may contain an element other than In, Ga, and Zn.

Further, the oxide semiconductor film is formed with a thin film using a material represented by the chemical formula, InMO₃(ZnO)ₘ (m>0). Here, M represents one or more metal elements selected from Ga, Al, Mn, and Co. For example, Ga, Ga and Al, Ga and Mn, Ga and Co, or the like may be used as M.

In the oxide semiconductor film, the band gap should be greater than or equal to 3 eV, preferably greater than or equal to 3 eV and less than 3.6 eV. In addition, the electron affinity should be greater than or equal to 4 eV, preferably greater than or equal to 4 eV and less than 4.9 eV. Furthermore, in such a material, the carrier concentration derived from a donor or an acceptor should be less than 1×10¹⁴ cm⁻³, preferably less than 1×10¹¹ cm⁻³. Further, in the oxide semiconductor film, the hydrogen concentration should be less than 1×10¹⁸ cm⁻³, preferably less than 1×10¹⁶ cm⁻³. In a thin film transistor including the above oxide semiconductor film as an active layer, the off-state current can take an extremely low value of 1 zA (zeptoampere, 10⁻²¹ A).

The gate insulating film 112 may have the same structure as the insulating film 102. In this case, a material having a high dielectric constant, such as hafnium oxide or aluminum oxide, may be used considering that it functions as the gate insulating film of the transistor. In addition, a material having a high dielectric constant, such as hafnium oxide or aluminum oxide, may be stacked on silicon oxide, silicon oxynitride, or silicon nitride considering a gate withstand voltage or the interface state between the oxide semiconductor and the gate insulating film, or the like.

A protective insulating film may be further provided over the transistor 151. The protective insulating film can have the same structure as the insulating film 102. Further, in order to electrically connect the source electrode 108a or the drain electrode 108b to a wiring, an opening may be formed in the insulating film 102, the gate insulating film 112, or the like. A second gate electrode may further be provided below the oxide semiconductor film 106. Note that the oxide semiconductor film 106 is preferably, but not necessarily, processed into an island shape.

Further, a conductive oxide film functioning as a source region and a drain region may be provided so as to serve as buffers between the oxide semiconductor film 106 and the source electrode 108a and between the oxide semiconductor film 106 and the drain electrode 108b.

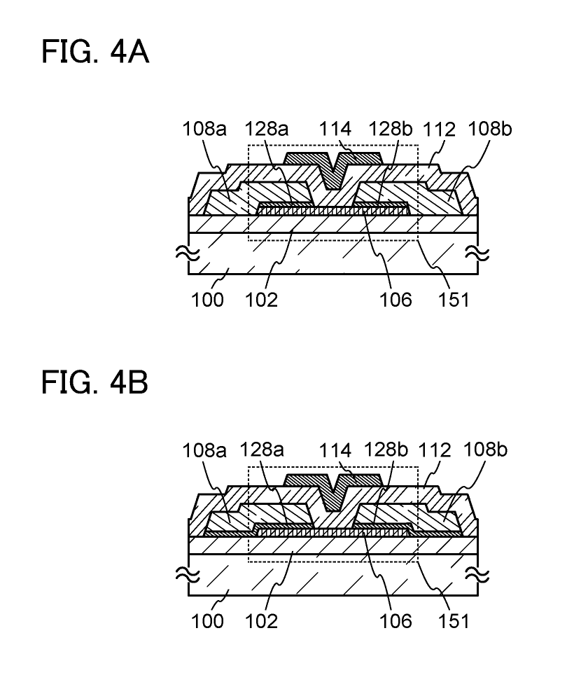

In FIG. 4A, a buffer 128a is provided between a portion where the oxide semiconductor film 106 and the source electrode 108a overlap, and a buffer 128b is provided between a portion where the oxide semiconductor film 106 and the drain electrode 108b overlap.

In FIG. 4B, the buffer 128a and the buffer 128b are provided in contact with lower portions of the source electrode 108a and the drain electrode 108b.

For the conductive oxide film, indium oxide (In₂O₃), tin oxide (SnO₂), zinc oxide (ZnO), indium oxide-tin oxide (In₂O₃—SnO₂, which is abbreviated to ITO), indium oxide-zinc oxide (In₂O₃—ZnO), or any of these metal oxide materials containing silicon oxide can be used.

By the provision of the conductive oxide film as the source region and the drain region between the oxide semiconductor film 106 and the source electrode 108a and between the oxide semiconductor film 106 and the drain electrode 108b, it is possible to reduce the contact resistance between the source region and the oxide semiconductor film 106 and between the drain region and the oxide semiconductor film 106, so that the transistor 151 can operate at high speed.

FIGS. 4A and 4B do not differ in the function of a buffer and illustrate examples that differ in form depending on the formation method.

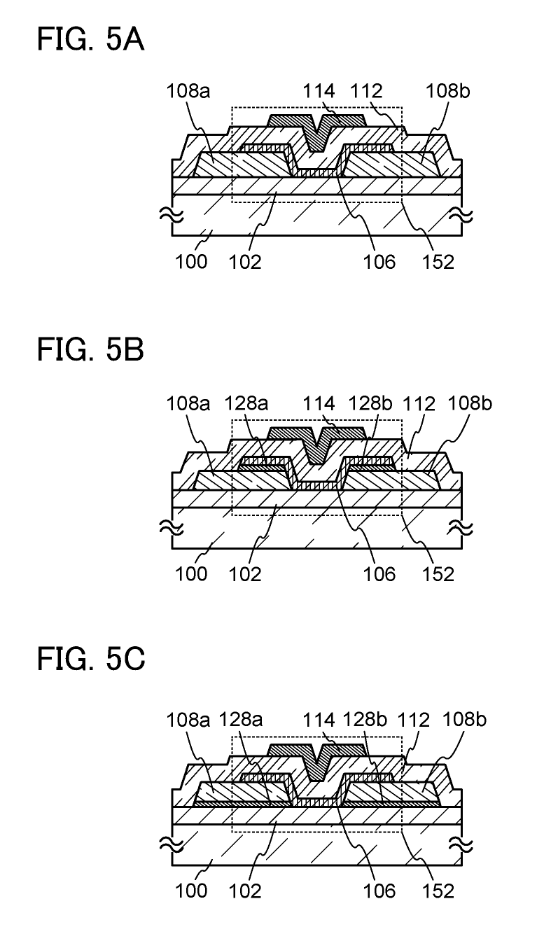

FIGS. 5A to 5C illustrate cross-sectional structures of transistors that differ in structure from the transistor 151.

A transistor 152 illustrated in FIG. 5A and the transistor 151 have something in common in that they include the insulating film 102, the oxide semiconductor film 106, the source electrode 108a, the drain electrode 108b, the gate insulating film 112, and the gate electrode 114. What makes the transistor 152 different from the transistor 151 is the positions where the oxide semiconductor film 106 is connected to the source electrode 108a and the drain electrode 108b. That is, in the transistor 152, the source electrode 108a and the drain electrode 108b are in contact with lower portions of the oxide semiconductor film 106. The other components are the same as those of the transistor 151 in FIGS. 1A and 1B.

Further, a conductive oxide film functioning as the source region and the drain region may be provided so as to serve as buffers between the oxide semiconductor film 106 and the source electrode 108a and between the oxide semiconductor film 106 and the drain electrode 108b.

In FIG. 5B, the buffer 128a is provided between a portion where the oxide semiconductor film 106 and the source electrode 108a overlap, and the buffer 128b is provided between a portion where the oxide semiconductor film 106 and the drain electrode 108b overlap. Note that, although not illustrated, the buffers 128a and the buffer 128b may be provided to have a top surface having the same form as the source electrode 108a and the drain electrode 108b.

In FIG. 5C, the buffer 128a is provided directly under the source electrode 108a, and the buffer 128b is provided directly under the drain electrode 108b. In this case, a side portion of the buffer 128a and a side portion of the buffer 128b are areas for electrical connection to the oxide semiconductor film 106.

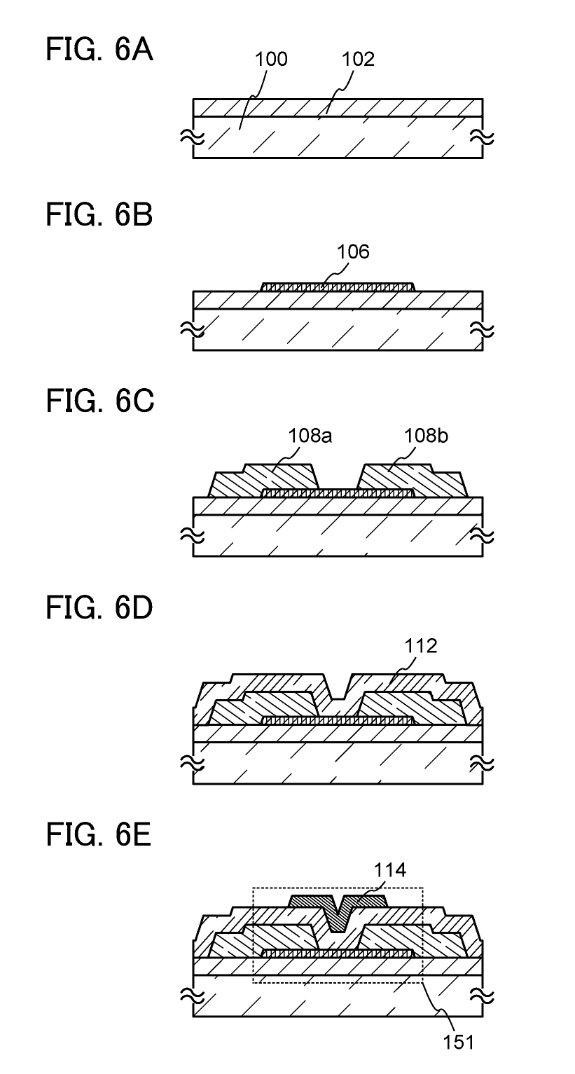

An example of a manufacturing process of the transistor 151 illustrated in FIGS. 3A to 3C will now be described using FIGS. 6A to 6E. Note that, in this embodiment, film formation and heat treatment or plasma treatment are conducted successively (in situ) in a vacuum state as much as possible. To begin with, a process using the film formation apparatus in FIG. 1A is described.

First, the substrate 100 is introduced into the load lock chamber 12a. Next, the substrate 100 is transferred to the substrate heating chamber 15, and hydrogen adsorbed to the substrate 100 is removed through first heat treatment, plasma treatment, or the like in the substrate heating chamber 15. Here, the first heat treatment is performed at a temperature greater than or equal to 100° C. and less than the strain point of the substrate in an inert atmosphere, a reduced-pressure atmosphere, or a dry air atmosphere. Further, for the plasma treatment, rare gas, oxygen, nitrogen, or nitrogen oxide (e.g., nitrous oxide, nitrogen monoxide, or nitrogen dioxide) is used. After that, the substrate 100 is transferred to the film formation chamber 10a with a leakage rate less than or equal to 1×10⁻¹⁰ Pa·m³/sec, and the insulating film 102 is formed by a sputtering method to a thickness greater than or equal to 50 nm and less than or equal to 500 nm, preferably greater than or equal to 200 nm and less than or equal to 400 nm (see FIG. 6A). Then, after the substrate 100 is transferred to the substrate heating chamber 15, second heat treatment may be performed at a temperature greater than or equal to 150° C. and less than or equal to 280° C., preferably greater than or equal to 200° C. and less than or equal to 250° C. in an inert atmosphere, a reduced-pressure atmosphere, or a dry air atmosphere. Through the second heat treatment, hydrogen can be removed from the substrate 100 and the insulating film 102. Note that the second heat treatment is performed at a temperature at which hydrogen is removed from the insulating film 102 but as less oxygen as possible is released. Then, the substrate 100 is transferred to the film formation chamber 10b with a leakage rate less than or equal to 1×10⁻¹⁰ Pa·m³/sec, and the oxide semiconductor film is formed by a sputtering method. Then, after the substrate 100 is transferred to the substrate heating chamber 15, third heat treatment may be performed at a temperature greater than or equal to 250° C. and less than or equal to 470° C. in an inert atmosphere, a reduced-pressure atmosphere, or a dry air atmosphere so that hydrogen is removed from the oxide semiconductor film while oxygen is supplied from the insulating film 102 to the oxide semiconductor film. Note that the third heat treatment is performed at a higher temperature than that of the second heat treatment by 5° C. or more. By use of the film formation apparatus in FIG. 1A in this manner, the manufacturing process can proceed with less entry of hydrogen in film formation.

Next, the same process as the above process using the film formation apparatus in FIG. 1B is described.

First, the substrate 100 is introduced into the load lock chamber 22a. Next, the substrate 100 is transferred to the substrate heating chamber 25, and hydrogen adsorbed to the substrate 100 is removed through first heat treatment, plasma treatment, or the like in the substrate heating chamber 25. Here, the first heat treatment is performed at a temperature greater than or equal to 100° C. and less than the strain point of the substrate in an inert atmosphere, a reduced-pressure atmosphere, or a dry air atmosphere. Further, for the plasma treatment, rare gas, oxygen, nitrogen, or nitrogen oxide (e.g., nitrous oxide, nitrogen monoxide, or nitrogen dioxide) is used. After that, the substrate 100 is transferred to the film formation chamber 20a with a leakage rate less than or equal to 1×10⁻¹⁰ Pa·m³/sec, and the insulating film 102 having a thickness of 300 nm is formed by a sputtering method (see FIG. 6A). Then, the substrate 100 is transferred to the film formation chamber 20b with a leakage rate less than or equal to 1×10⁻¹⁰ Pa·m³/sec, and the oxide semiconductor film having a thickness of 30 nm is formed by a sputtering method. By use of the film formation apparatus in FIG. 1B in this manner, the manufacturing process can proceed with less entry of hydrogen during film formation.

Here, in the substrate heating chamber 15 or the substrate heating chamber 25, high-temperature heat treatment in a short period is possible by use of GRTA treatment, in which the substrate is put into a heated inert atmosphere, so that an improvement of the throughput can be realized. Moreover, the GRTA treatment can be used even in the conditions where the temperature exceeds the upper temperature limit of the substrate. Note that the inert atmosphere may be switched to an oxidation atmosphere during the treatment. Through the heat treatment in an oxidation atmosphere, oxygen deficiency in the oxide semiconductor film can be filled and defect levels in an energy gap due to the oxygen deficiency can be reduced.

The thickness of the oxide semiconductor film is preferably greater than or equal to 3 nm and less than or equal to 50 nm. This is because, if the oxide semiconductor film is too thick (e.g., a thickness of 100 nm or more), the influence of a short-channel effect is increased and a small-sized transistor could be normally on.

In this embodiment, the oxide semiconductor film is formed using an In—Ga—Zn—O-based oxide target.

As the In—Ga—Zn—O-based oxide target, for example, an oxide target containing In₂O₃, Ga₂O₃, and ZnO at a composition ratio of 1:1:1 [molar ratio] can be used. Note that there is no need to limit the material and composition ratio of the target to the above. For example, an oxide target containing In₂O₃, Ga₂O₃, and ZnO at a composition ratio of 1:1:2 [molar ratio] can also be used.

The relative density of the oxide target is greater than or equal to 90% and less than or equal to 100%, preferably greater than or equal to 95% and less than or equal to 100%. This is because, with the use of the oxide target with a high relative density, the formed oxide semiconductor film can be a dense film.

The formation of the oxide semiconductor film can be performed under a rare gas atmosphere, an oxygen atmosphere, a mixed atmosphere containing a rare gas and oxygen, or the like.

For example, the oxide semiconductor film can be formed under the following conditions: the distance between the substrate and the target is 60 mm; the pressure is 0.4 Pa; the direct-current (DC) power is 0.5 kW; and the film formation atmosphere is a mixed atmosphere containing argon and oxygen (the flow rate of the oxygen is 33%). Note that a pulse DC sputtering method is preferably used because powder substances (also referred to as particles or dust) generated in film formation can be reduced and the film thickness can be uniform. The substrate temperature is greater than or equal to 100° C. and less than or equal to 400° C. Through the film formation performed with the substrate 100 heated, the concentration of excessive hydrogen and other impurities contained in the oxide semiconductor film can be reduced. In addition, damage due to sputtering can be reduced. Further, oxygen is released from the insulating film 102, and oxygen deficiency in the oxide semiconductor film and the interface state density between the insulating film 102 and the oxide semiconductor film can be reduced.

After the substrate 100 is exposed to air, the oxide semiconductor film may be subjected to the third heat treatment. Through the third heat treatment, excessive hydrogen in the oxide semiconductor film can be removed and a structure of the oxide semiconductor film can be ordered. The temperature of the third heat treatment is greater than or equal to 100° C. and less than or equal to 650° C. or less than the strain point of the substrate, preferably greater than or equal to 250° C. and less than or equal to 600° C., further preferably greater than or equal to 250° C. and less than or equal to 450° C. The heat treatment is performed in an oxidation atmosphere or an inert atmosphere. Further, oxygen is released from the insulating film 102, and oxygen deficiency in the oxide semiconductor film and the interface state density between the insulating film 102 and the oxide semiconductor film can be reduced.

The third heat treatment can be performed in such a way that, for example, an object to be heated is introduced into an electric furnace using a resistance heater or the like and heated at 350° C. for one hour in a nitrogen atmosphere. The oxide semiconductor film is not exposed to air during this heat treatment so that entry of water or hydrogen can be prevented.

Note that an apparatus for the third heat treatment is not limited to an electric furnace, and an apparatus with which an object to be processed is heated by heat conduction or heat radiation from a medium such as a heated gas may be used; for example, an RTA apparatus can be used.

Incidentally, the same heat treatment as the third heat treatment may be repeated for the substrate 100 in the subsequent process.

Note that the oxidation atmosphere refers to an atmosphere of an oxidation gas (e.g., an oxygen gas, an ozone gas, or a nitrogen oxide gas) and preferably does not contain hydrogen or the like. For example, the purity of the oxidation gas to be introduced is 8N (99.999999%) or more, preferably 9N (99.9999999%) or more. The oxidation atmosphere, as which an oxidation gas mixed with an inert gas may be used, contains an oxidation gas at least at a concentration of 10 ppm or more.

Next, the oxide semiconductor film is processed to form the island-shaped oxide semiconductor film 106 (see FIG. 6B).

The oxide semiconductor film 106 can be processed by being etched after a mask having a desired shape is formed over the oxide semiconductor film. The mask can be formed by a method such as photolithography. Alternatively, the mask may be formed by a method such as an inkjet method.

Next, a conductive film for forming the source electrode and the drain electrode (including a wiring formed with the same film) is formed over the insulating film 102 and the oxide semiconductor film 106, and the conductive film is processed to form the source electrode 108a and the drain electrode 108b (see FIG. 6C). Note that the channel length L of the transistor is determined by the distance between edge portions of the source electrode 108a and the drain electrode 108b which are formed here.

As the conductive film used for the source electrode 108a and the drain electrode 108b, for example, a metal film containing an element selected from Al, Cr, Cu, Ta, Ti, Mo, and W or a metal nitride film containing any of the above elements as the main component (e.g., a titanium nitride film, a molybdenum nitride film, or a tungsten nitride film) can be used. A structure may be used in which a film of high-melting-point metal, such as Ti, Mo, or W, or a metal nitride film of any of these elements (e.g., a titanium nitride film, a molybdenum nitride film, or a tungsten nitride film) is stacked on one or both of a lower and upper sides of a metal film of Al, Cu, or the like. Note that the conductive film to serve as the source electrode 108a and the drain electrode 108b may be formed with the apparatus described in Embodiment 1.

The conductive film used for the source electrode 108a and the drain electrode 108b may be formed with a conductive metal oxide. As the conductive metal oxide, In₂O₃, SnO₂, ZnO, ITO, In₂O₃—ZnO, or any of these metal oxide materials in which silicon or silicon oxide is contained can be used.

The conductive film may be processed by etching with the use of a resist mask. For light exposure in formation of the resist mask used for the etching, ultraviolet, a KrF laser light, an ArF laser light, or the like is preferably used.

Note that in the case where the light exposure is performed so that the channel length L is less than 25 nm, for example, extreme ultraviolet having an extremely short wavelength of several nanometers to several tens of nanometers is preferably used for the light exposure in formation of the resist mask. In the light exposure with extreme ultraviolet light, the resolution is high and the focus depth is large. Thus, the channel length L of the transistor formed later can be reduced, and the operation speed of a circuit can be increased.

Furthermore, a resist mask formed with a so-called multi-tone mask may be used for the etching. Since the resist mask formed with a multi-tone mask has a plurality of thicknesses and can be further changed in shape by ashing, the resist mask can be used in a plurality of etching steps for different patterns. Thus, with one multi-tone mask, a resist mask corresponding to at least two or more kinds of different patterns can be formed; that is, the process can be simplified.

Note that, in the etching of the conductive film, part of the oxide semiconductor film 106 might be etched to be an oxide semiconductor film having a groove portion (a recessed portion).

Note that a conductive oxide film functioning as the source region and the drain region may be provided so as to serve as buffers between the oxide semiconductor film 106 and the source electrode 108a and between the oxide semiconductor film 106 and the drain electrode 108b.

In this case, a stack of the oxide semiconductor film and the conductive oxide film is formed, and the shape of the stack of the oxide semiconductor film and the conductive oxide film is processed in one photolithography step to form the island-shaped oxide semiconductor film 106 and the island-shaped conductive oxide film. After the source electrode 108a and the drain electrode 108b are formed over the oxide semiconductor film 106 and the conductive oxide film, the buffers are formed in such a way that the conductive oxide film is etched with the source electrode 108a and the drain electrode 108b as a mask and divided into the source region and the drain region.

Alternatively, the conductive oxide film is formed over the oxide semiconductor film 106, a conductive film is formed thereover, and the conductive oxide film and the conductive film are processed in one photolithography step, so that the buffers serving as the source region and the drain region are formed in contact with the lower portions of the source electrode 108a and the drain electrode 108b.

As a film formation method for the conductive oxide film, a sputtering method, a vacuum evaporation method (e.g., an electron beam evaporation method), an arc discharge ion plating method, or a spray method is used.

Next, the gate insulating film 112 is formed so as to cover the source electrode 108a and the drain electrode 108b and to be in contact with part of the oxide semiconductor film 106 (see FIG. 6D).

Note that plasma treatment using an oxidation gas may be performed just before the formation of the gate insulating film 112 so that an exposed surface of the oxide semiconductor film 106 is oxidized and oxygen deficiency is filled. When performed, the plasma treatment preferably follows the formation of the gate insulating film 112 which is to be in contact with part of the oxide semiconductor film 106 without exposure to the air.

The gate insulating film 112 can have the same structure as the base insulating film 102. The total thickness of the gate insulating film 112 is preferably greater than or equal to 1 nm and less than or equal to 300 nm, more preferably greater than or equal to 5 nm and less than or equal to 50 nm. As the thickness of the gate insulating film is larger, a short channel effect is enhanced more and the threshold voltage tends to easily shift in the negative direction. In addition, leakage due to a tunnel current is found to be increased with a thickness of the gate insulating film of 5 nm or less. Note that the gate insulating film 112 may be formed with the apparatus described in Embodiment 1.

After that, a conductive film is formed and processed by a photolithography step to form the gate electrode 114 (see FIG. 6E). The gate electrode 114 can be formed using a metal material such as molybdenum, titanium, tantalum, tungsten, aluminum, copper, neodymium, or scandium, nitride of any of these metal materials, or an alloy material which contains any of these metal materials as the main component. Note that the gate electrode 114 may have a single-layer structure or a stack structure.

Through the above process, the transistor 151 is formed.

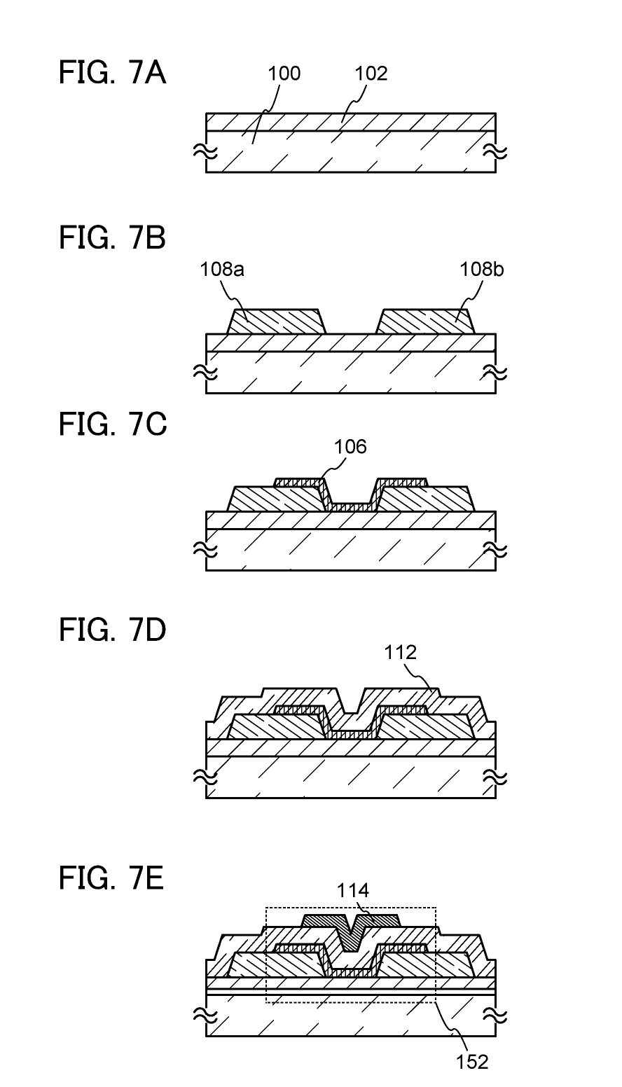

Next, an example of a manufacturing process of the transistor 152 illustrated in FIG. 5A will be described with reference to FIGS. 7A to 7E. Note that, in this embodiment, a manufacturing method using the film formation apparatus in FIG. 1A is used is described.

First, the substrate 100 is transferred into the load lock chamber 12a from the substrate supply chamber 11. Next, the substrate 100 is transferred to the substrate heating chamber 15 through the load lock chamber 12a and the transfer chamber 13, and hydrogen adsorbed to the substrate 100 is removed through first heat treatment, plasma treatment, or the like in the substrate heating chamber 15. After that, the substrate 100 is transferred to the film formation chamber 10c with a leakage rate less than or equal to 1×10⁻¹⁰ Pa·m³/sec through the transfer chamber 13, and the insulating film 102 having a thickness of 300 nm is formed by a sputtering method (see FIG. 7A). After that, the conductive film is formed.

The substrate is temporarily taken out from the film formation apparatus, the conductive film is processed by a photolithography step to form the source electrode 108a and the drain electrode 108b (see FIG. 7B).

Note that a conductive oxide film functioning as the source region and the drain region may be provided so as to serve as the buffers between the insulating film 102 and the source electrode 108a and between the insulating film 102 and the drain electrode 108b.

In this case, a stack of the conductive oxide film and the conductive film is formed over the insulating film 102, and the shape of the stack of the conductive oxide film and the conductive film should be processed in one photolithography step to form the buffers serving as the source region and the drain region, lower portions of which are in contact with the source electrode 108a and the drain electrode 108b.

Alternatively, a stack of the conductive film and the conductive oxide film may be formed over the insulating film 102 and processed in one photolithography step, so that the buffers serving as the source region and the drain region are formed in contact with the upper portions of the source electrode 108a and the drain electrode 108b.

Next, the substrate 100 is transferred into the load lock chamber 12a from the substrate supply chamber 11. Next, the substrate 100 is transferred to the substrate heating chamber 15 through the load lock chamber 12a and the transfer chamber 13, and hydrogen adsorbed to the substrate 100 is removed by first heat treatment, plasma treatment, or the like in the substrate heating chamber 15. After that, the substrate 100 is transferred to the film formation chamber 10b with a leakage rate less than or equal to 1×10⁻¹⁰ Pa·m³/sec through the transfer chamber 13, and the oxide semiconductor film is formed by a sputtering method. By use of the film formation apparatus in FIG. 1A in this manner, the manufacturing process can proceed with less entry of hydrogen during film formation.

Next, the oxide semiconductor film is processed to form the island-shaped oxide semiconductor film 106 (see FIG. 7C). After that, the same first heat treatment as for the transistor 151 may be performed.

Note that in the case where the buffers respectively serving as the source region and the drain region are formed in contact with the upper portions of the source electrode 108a and the drain electrode 108b, the buffers might also be processed in the processing for the oxide semiconductor film 106. Even in this case, the function of the buffers does not change despite a change in the ultimate shape of the cross section.

Next, the gate insulating film 112 is formed so as to cover the oxide semiconductor film 106 and to be in contact with part of the source electrode 108a and the drain electrode 108b (see FIG. 7D).

After that, a conductive film is formed and processed by a photolithography step to form the gate electrode 114 (see FIG. 7E).

Through the above process, the transistor 152 is formed.

As described above, according to this embodiment, a semiconductor device using an oxide semiconductor with less variation in electrical characteristics can be provided. Further, a semiconductor device with high reliability can be provided.

The structures and methods described in this embodiment can be combined as appropriate with any of the structures and methods described in the other embodiments.

### Embodiment 3

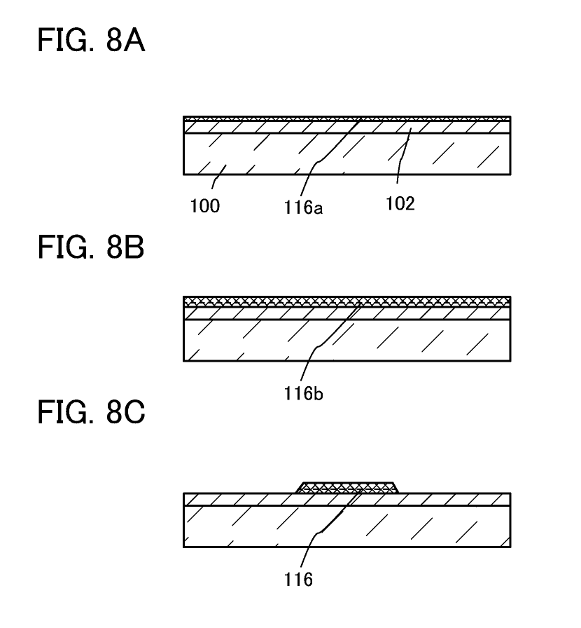

One mode of a film formation method for an oxide semiconductor film that can be used for a semiconductor film of a transistor in Embodiment 2 will be described using FIGS. 8A to 8C.

The oxide semiconductor film of this embodiment has a stack structure including a first crystalline oxide semiconductor film and a second crystalline oxide semiconductor film thereover which is thicker than the first crystalline oxide semiconductor film.

First, the insulating film 102 is formed over the substrate 100.

Next, a first oxide semiconductor film having a thickness greater than or equal to 1 nm and less than or equal to 10 nm is formed over the insulating film 102. A sputtering method is used for the formation of the first oxide semiconductor film. The substrate temperature during the film formation is greater than or equal to 100° C. and less than or equal to 400° C.

In this embodiment, the first oxide semiconductor film having a thickness of 5 nm is formed using a target for an oxide semiconductor (a target for an In—Ga—Zn—O-based oxide semiconductor containing In₂O₃, Ga₂O₃, and ZnO at 1:1:2 [molar ratio]), with a distance between the substrate and the target of 60 mm, a substrate temperature of 200° C., a pressure of 0.4 Pa, and a direct current (DC) power source of 0.5 kW in an atmosphere of only oxygen, only argon, or argon and oxygen.

Next, the atmosphere in the film formation chamber where the substrate is placed is set to nitrogen or dry air, and first crystallization heat treatment is performed. The temperature of the first crystallization heat treatment is greater than or equal to 400° C. and less than or equal to 750° C. A first crystalline oxide semiconductor film 116a is formed by the first crystallization heat treatment (see FIG. 8A).

Depending on the temperature of the first crystallization heat treatment, the first crystallization heat treatment causes crystallization from a film surface and crystal growth from the film surface toward the inside of the film; thus, c-axis aligned crystal is obtained. By the first crystallization heat treatment, the proportions of zinc and oxygen in the film surface are increased, and one or more layers of graphene-type two-dimensional crystal including zinc and oxygen and having a hexagonal upper plane are formed at the outermost surface; the layers grow in the thickness direction to overlap with each other. By an increase in the temperature of the crystallization heat treatment, the crystal growth proceeds from the surface to the inside and further from the inside to the bottom.

By the first crystallization heat treatment, oxygen in the insulating film 102 is diffused into an interface between the insulating film 102 and first crystalline oxide semiconductor film 116a or the vicinity of the interface (within ±5 nm from the interface), so that oxygen vacancy in the first crystalline oxide semiconductor film and the interface state between the insulating film 102 and the first crystalline oxide semiconductor film 116a can be reduced.

Next, a second oxide semiconductor film with a thickness greater than 10 nm is formed over the first crystalline oxide semiconductor film 116a. In formation of the second crystalline oxide semiconductor film, a sputtering method is used, and a substrate temperature is greater than or equal to 100° C. and less than or equal to 400° C. With a substrate temperature greater than or equal to 100° C. and less than or equal to 400° C. in the film formation, precursors can be arranged in the oxide semiconductor film formed over and in contact with the surface of the first crystalline oxide semiconductor film and so-called orderliness can be obtained.

In this embodiment, the second oxide semiconductor film is formed to a thickness of 25 nm in an oxygen atmosphere, an argon atmosphere, or a mixed atmosphere of argon and oxygen in the conditions where a target for an oxide semiconductor (a target for an In—Ga—Zn—O-based oxide semiconductor containing In₂O₃, Ga₂O₃, and ZnO at 1:1:2 [molar ratio]) is used, the distance between the substrate and the target is 60 mm, the substrate temperature is 400° C., the pressure is 0.4 Pa, and the direct current (DC) power source is 0.5 kW.

Then, second crystallization heat treatment is performed. The temperature of the second crystallization heat treatment is greater than or equal to 400° C. and less than or equal to 750° C. A second crystalline oxide semiconductor film 116b is formed by the second crystallization heat treatment (see FIG. 8B). Here, the second crystalline heat treatment is preferably performed in a nitrogen atmosphere, an oxygen atmosphere, or a mixed atmosphere of argon and oxygen so that the density of the second crystalline oxide semiconductor film can be increased and the number of defects therein can be reduced. By the second crystallization heat treatment, crystal growth proceeds in the thickness direction with the use of the first crystalline oxide semiconductor film 116a as a nucleus, that is, crystal growth proceeds from the bottom to the inside; thus, the second crystalline oxide semiconductor film 116b is formed.

It is preferable that the steps from the formation step of the oxide insulating film 102 to the step of the second crystalline heat treatment be performed successively without exposure to air. For example, a film formation apparatus whose top view is illustrated in FIG. 1A should be used. The atmospheres in the film formation chambers 10a to 10c, the transfer chamber 13, and the substrate heating chamber 15 are preferably controlled so as to hardly contain hydrogen and moisture; in terms of moisture, for example, a dry nitrogen atmosphere with a dew point of −40° C. or less, preferably a dew point of −50° C. or less is employed. An example of a procedure of the manufacturing steps with use of the film formation apparatus illustrated in FIG. 1A is as follows. The substrate 100 is first transferred from the substrate supply chamber 11 to the substrate heating chamber 15 through the load lock chamber 12a and the transfer chamber 13; hydrogen adhering to the substrate 100 is removed by vacuum baking or the like in the substrate heating chamber 15; the substrate 100 is then transferred to the film formation chamber 10c through the transfer chamber 13; and the insulating film 102 is formed in the film formation chamber 10c. Then, the substrate 100 is transferred to the film formation chamber 10a through the transfer chamber 13 without exposure to air, and the first oxide semiconductor film having a thickness of 5 nm is formed in the film formation chamber 10a. Then, the substrate 100 is transferred to the substrate heating chamber 15 though the transfer chamber 13 without exposure to air and first crystallization heat treatment is performed. Then, the process temperature is transferred to the film formation chamber 10a through the transfer chamber 13, and the second oxide semiconductor film having a thickness greater than 10 nm is formed in the film formation chamber 10a. Then, the substrate 100 is transferred to the substrate heating chamber 15 through the transfer chamber 13, and second crystallization heat treatment is performed. As described above, with use of the film formation apparatus illustrated in FIG. 1A, a manufacturing process can proceed without exposure to air. Further, after a stack of the insulating film 102, the first crystalline oxide semiconductor film, and the second crystalline oxide semiconductor film is formed, in the film formation chamber 10b, a conductive film for forming a source electrode and a drain electrode can be formed over the second crystalline oxide semiconductor film with use of a metal target, without exposure to air. Note that the first crystalline oxide semiconductor film and the second crystalline oxide semiconductor film may be formed in separate film formation chambers for improvement of the throughput.

Next, a stack of an oxide semiconductor film including the first crystalline oxide semiconductor film 116a and the second crystalline oxide semiconductor film 116b is processed to form an oxide semiconductor film 116 including the island-shaped stack of oxide semiconductor films (see FIG. 8C). In the drawings, the interface between the first crystalline oxide semiconductor film 116a and the second crystalline oxide semiconductor film 116b is indicated by a dashed line for description of the stack of oxide semiconductor films; however, the interface is actually not distinct and is illustrated for easy understanding.

The stack of the oxide semiconductor films can be processed by etching after a mask having a desired shape is formed over the stack of the oxide semiconductor films. The above mask may be formed by a method such as photolithography. Alternatively, the mask may be formed by a method such as an inkjet method.

Further, one feature of the first crystalline oxide semiconductor film and second crystalline oxide semiconductor film obtained by the above formation method is that they have c-axis alignment. Note that the first crystalline oxide semiconductor film and the second crystalline oxide semiconductor film have neither a single crystal structure nor an amorphous structure and are crystalline oxide semiconductors having c-axis alignment (c-axis aligned crystalline (CAAC) oxide semiconductors). Further, the first crystalline oxide semiconductor film and the second crystalline oxide semiconductor film partly include a crystal grain boundary.

Note that the first crystalline oxide semiconductor film and the second crystalline oxide semiconductor film are each formed using an oxide material containing at least Zn, and any of the following materials can be used: oxides of four metal elements, such as an In—Al—Ga—Zn—O-based material, an In—Al—Ga—Zn—O based material, and an In—Sn—Ga—Zn—O-based material; oxides of three metal elements, such as an In—Ga—Zn—O-based material, an In—Al—Zn—O-based material, an In—Sn—Zn—O-based material, a Sn—Ga—Zn—O-based material, an Al—Ga—Zn—O-based material, and a Sn—Al—Zn—O-based material; oxides of two metal elements, such as an In—Zn—O-based material, a Sn—Zn—O-based material, an Al—Zn—O-based material, and a Zn—Mg—O-based material; a Zn—O-based material; and the like. Also, an In—Si—Ga—Zn—O-based based material, an In—Ga—B—Zn—O-based material, and an In—B—Zn—O-based material can be used. In addition, the above materials may contain SiO₂. Here, for example, an In—Ga—Zn—O-based material means an oxide containing indium (In), gallium (Ga), and zinc (Zn), and there is no particular limitation on the composition ratio. Further, the In—Ga—Zn—O-based oxide semiconductor may contain an element other than In, Ga, and Zn.

Without limitation to the two-layer structure in which the second crystalline oxide semiconductor film is formed over the first crystalline oxide semiconductor film, a stack structure of three or more layers may be formed by repeatedly performing a process of film formation and crystallization heat treatment for forming a third crystalline oxide semiconductor film after the second crystalline oxide semiconductor film is formed.

The oxide semiconductor film 116 including the stack of the oxide semiconductor films formed by the above formation method can be used as appropriate for a transistor which can be applied to a semiconductor device disclosed in this specification (e.g., the transistor 151 or the transistor 152 in Embodiment 2).

In the transistor 151 according to Embodiment 2, in which the stack of the oxide semiconductor films of this embodiment is used as the oxide semiconductor film 106, an electric field is not applied from one surface to the other surface of the oxide semiconductor film and current does not flow in the thickness direction (from one surface to the other surface; specifically, in the vertical direction in FIG. 3B) of the stack of the oxide semiconductor films. The transistor has a structure in which current mainly flows along the interface of the stack of the oxide semiconductor films; therefore, even when the transistor is irradiated with light or even when a bias-temperature (BT) stress is applied to the transistor, deterioration of electrical characteristics is suppressed or reduced.

By using a stack of a first crystalline oxide semiconductor film and a second crystalline oxide semiconductor film, like the oxide semiconductor film 116, a transistor having stable electric characteristics and high reliability can be realized.

This embodiment can be implemented in an appropriate combination with any of the structures described in the other embodiments.

### Example 1

In this example, a method of starting a film formation chamber of a sputtering apparatus, which is a film formation apparatus, and the hydrogen concentration in an oxide semiconductor film formed using the film formation chamber will be described.

Six kinds of samples were prepared. Sample A, Sample B, and Sample C were prepared by the following method. First, after the film formation chamber of the sputtering apparatus was opened to air, the film formation chamber was sealed, and vacuum was drawn using a dry pump and a cryopump until the pressure in the film formation chamber become 5×10⁻⁴ Pa. Next, one-minute dummy film formation at room temperature was conducted for 100 substrates, and then after the pressure in the film formation chamber become 8×10⁻⁵ Pa or less, an oxide semiconductor film was formed over a silicon wafer. Note that in the dummy film formation for 100 substrates, dummy film formation is conducted in batches of 20 substrates five times and vacuum was drawn for one hour or more between batches.

Sample D, Sample E, and Sample F were prepared by the following method. First, after the film formation chamber of the sputtering apparatus was opened to air, the film formation chamber was sealed, and vacuum was drawn using a dry pump and a cryopump until the pressure in the film formation chamber become 5×10⁻⁴ Pa. Then, a substrate holder was heated to a temperature at which the substrate temperature become 410° C., the temperature of the film formation chamber itself was set to 200° C., and then vacuum was further drawn until the pressure in the film formation chamber become 5×10⁻⁴ Pa. Next, five-minute dummy film formation was conducted for 100 substrates, and then, after the pressure in the film formation chamber become 9×10⁻⁵ Pa or less, an oxide semiconductor film was formed. Note that in the dummy film formation for 100 substrates, dummy film formation is conducted in batches of 20 substrates five times and vacuum was drawn for one hour or more between batches.

The film formation conditions for the oxide semiconductor film were as follows: an In—Ga—Zn—O target (In₂O₃:Ga₂O₃:ZnO=1:1:2 [molar ratio] with a relative density of 95% or more) was used; the electric power for the film formation was set to 500 W (DC); the pressure for the film formation was set to 0.4 Pa; the gas for the film formation was argon at 30 sccm and oxygen at 15 sccm; the distance between the target and the substrate was set to 60 mm; and the substrate temperature during the film formation was set to room temperature (Sample A and Sample D), 250° C. (Sample B and Sample E), and 400° C. (Sample C and Sample F). Note that the dummy film formation was conducted under the same conditions as the above oxide semiconductor film except the substrate temperature during the film formation.

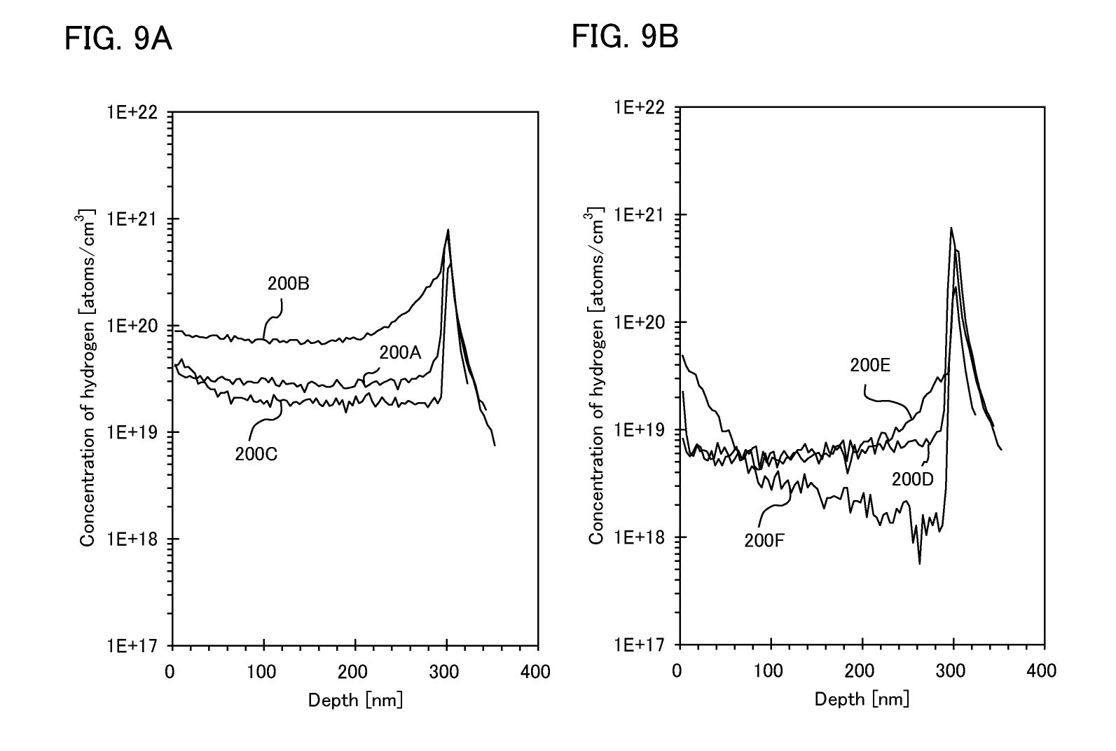

The hydrogen concentrations in the oxide semiconductor films of Samples A to F were measured by SIMS (secondary ion mass spectrometry), the results of which are shown in FIGS. 9A and 9B. Here, a solid line 200A corresponds to Sample A, a solid line 200B corresponds to Sample B, a solid line 200C corresponds to Sample C, a solid line 200D corresponds to Sample D, a solid line 200E corresponds to Sample E, and a solid line 200F corresponds to Sample F. Note that in FIGS. 9A and 9B, each hydrogen concentration in the oxide semiconductor film is shown in the depth range up to about 300 nm.

FIG. 9A reveals that Sample B formed with the substrate temperature set to 250° C. showed a higher hydrogen concentration in the oxide semiconductor film than Sample A formed with the substrate temperature set to room temperature. It is understood that this was because, in the formation of the oxide semiconductor film, a gas molecule adsorbed to the inner wall of the film formation chamber was desorbed by radiant heat due to heating of the substrate and was introduced in the oxide semiconductor film. Further, Sample C formed with the substrate temperature set to 400° C. was found to have a lower hydrogen concentration in the oxide semiconductor film than Sample A formed with the substrate temperature set to room temperature. It is understood that this was because a gas molecule adsorbed to the inner wall of the film formation chamber was desorbed and introduced in the oxide semiconductor film and because degassing from the oxide semiconductor film occurred during the formation of the oxide semiconductor film. In other words, it is understood that the ratio between the gas molecule introduced in the oxide semiconductor film and the released gas molecule determined the value of the hydrogen concentration in the oxide semiconductor film which is shown in the figure.

FIG. 9B reveals that there is little difference in the hydrogen concentration in the oxide semiconductor film between Sample D formed with the substrate temperature set to room temperature and Sample E formed with the substrate temperature set to 250° C. It is understood that this was because the gas molecule adsorbed to the inner wall of the film formation chamber was desorbed by an increase in the temperature of the film formation chamber itself and by the dummy film formation during heating was performed. Further, Sample F formed with the substrate temperature set to 400° C. was found to have a lower hydrogen concentration in the oxide semiconductor film than Sample D formed with the substrate temperature set to room temperature. It is understood that this was because degassing from the inner wall of the film formation chamber little occurred and degassing from the oxide semiconductor film occurred during the formation of the oxide semiconductor film.

Thus, it is found that, depending on processing conditions before the formation of the oxide semiconductor film (conditions for starting the film formation chamber), the rate of desorption of hydrogen in the film formation chamber can be increased and the hydrogen concentration in the oxide semiconductor film can be further reduced.

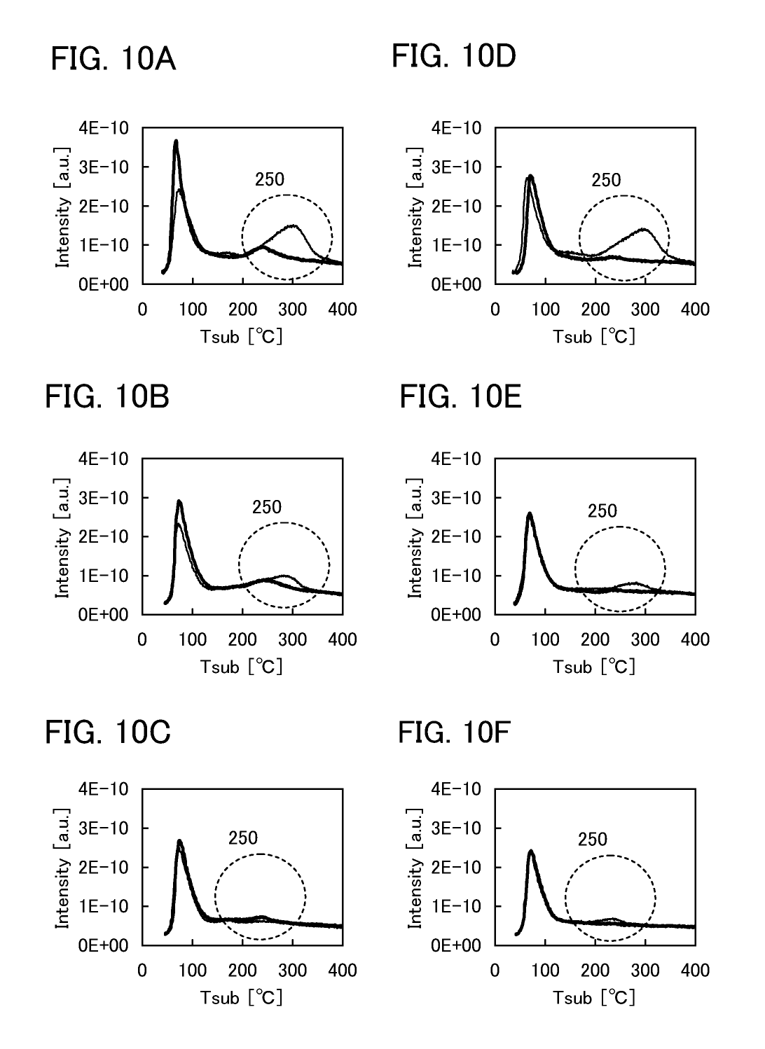

Next, with the same Samples A to F, spectra obtained by TDS analysis when the value of m/z was 18 were compared. The TDS spectra of Samples A to F are shown in FIGS. 10A to 10F. Note that the figures also show TDS spectra obtained in the case where, before the formation of the oxide semiconductor film, the silicon wafer was subjected to heat treatment (also referred to as substrate heat treatment) with the substrate temperature set to 400° C. for 5 minutes in a reduced-pressure atmosphere of 1×10⁻⁵ Pa. Note also that for a sample which was subjected to the substrate heat treatment, the oxide semiconductor film was formed successively in a vacuum. Here, there is H₂O as a gas molecule having a spectrum obtained when the value of m/z is 18.

FIGS. 10A to 10F show TDS spectra of Samples A to F. A peak 250 in each of FIGS. 10A to 10F is understood as H₂O from the inside of a sample, a substrate surface, or the like, which is released by the break in a bond with relatively high energy.

Comparison of the peaks 250 was made between the sample subjected to the substrate heat treatment and the sample which was not subjected to the substrate heat treatment. In each of FIGS. 10A to 10F, the thin line represents a spectrum of the sample without the substrate heat treatment and the thick line represents a spectrum of the sample subjected to the substrate heat treatment. While there appears little difference in the amount of released H₂O which depends on whether the substrate heat treatment was performed or not as for Samples C and F, it is found as for the other Samples that the sample subjected to the substrate heat treatment shows a smaller amount of released H₂O than the sample without the substrate heat treatment.

It is understood that this was because the gas molecule adsorbed to the substrate surface was able to be removed through the substrate heat treatment.

As described above, it is found that, through the substrate heat treatment before the formation of the oxide semiconductor film, the gas molecule adsorbed to the substrate surface can be removed and the amount of H₂O released from the oxide semiconductor film can be reduced.

This application is based on Japanese Patent Application serial No. 2010-183025 filed with the Japan Patent Office on Aug. 18, 2010 and Japanese Patent Application serial No. 2011-083966 filed with the Japan Patent Office on Apr. 5, 2011, the entire contents of which are hereby incorporated by reference.

What is claimed is:

1. A film formation apparatus comprising:
a load lock chamber, a transfer chamber connected to the load lock chamber through a first gate valve;
a substrate heating chamber connected to the transfer chamber through a second gate valve; and
a film formation chamber being connected to the transfer chamber through a third gate valve and having a leakage rate less than or equal to 1×10⁻¹⁰ Pa·m³/sec.

2. The film formation apparatus according to claim 1, comprising a plurality of the film formation chambers.

3. The film formation apparatus according to claim 1, comprising a plurality of the load lock chambers.

4. A film formation apparatus comprising:
a load lock chamber;
a substrate heating chamber connected to the load lock chamber through a first gate valve; and
a film formation chamber being connected to the substrate heating chamber through a second gate valve and having a leakage rate less than or equal to 1×10⁻¹⁰ Pa·m³/sec.

5. A film formation apparatus comprising:
a load lock chamber;
a substrate heating chamber connected to the load lock chamber through a first gate valve;
a first film formation chamber being connected to the substrate heating chamber through a second gate valve and having a leakage rate less than or equal to 1×10⁻¹⁰ Pa·m³/sec; and
a second film formation chamber being connected to the first film formation chamber through a third gate valve and having a leakage rate less than or equal to 1×10⁻¹⁰ Pa·m³/sec.

6. The film formation apparatus according to claim 1,
wherein the substrate heating chamber also serves as a plasma treatment chamber.

7. The film formation apparatus according to claim 4,
wherein the substrate heating chamber also serves as a plasma treatment chamber.

8. The film formation apparatus according to claim 5,
wherein the substrate heating chamber also serves as a plasma treatment chamber.

9. The film formation apparatus according to claim 1,
wherein a distance between a target and a substrate in the film formation chamber is shorter than a mean free path of a sputtered particle, a gas molecule, or an ion.

10. The film formation apparatus according to claim 4,
wherein a distance between a target and a substrate in the film formation chamber is shorter than a mean free path of a sputtered particle, a gas molecule, or an ion.

11. The film formation apparatus according to claim 5,
wherein a distance between a target and a substrate in at least one of the first film formation chamber and the second film formation chamber is shorter than a mean free path of a sputtered particle, a gas molecule, or an ion.

12. The film formation apparatus according to claim 9, wherein the distance is less than or equal to 25 mm.

13. The film formation apparatus according to claim 10, wherein the distance is less than or equal to 25 mm.

14. The film formation apparatus according to claim 11, wherein the distance is less than or equal to 25 mm.

15. The film formation apparatus according to claim 1, further comprising:
a source of a film formation gas; and
a gas refiner between the source of the film formation gas and the film formation chamber.

16. The film formation apparatus according to claim 4, further comprising:
a source of a film formation gas; and
a gas refiner between the source of the film formation gas and the film formation chamber.

17. The film formation apparatus according to claim 5, further comprising:
a source of a film formation gas;
a gas refiner between the source of the film formation gas and at least one of the first film formation chamber and the second film formation chamber.

18. The film formation apparatus according to claim 15,
wherein a length of a pipe between the gas refiner and the film formation chamber is less than or equal to 5 m.

19. The film formation apparatus according to claim 16,
wherein a length of a pipe between the gas refiner and the film formation chamber is less than or equal to 5 m.

20. The film formation apparatus according to claim 17,
wherein a length of a pipe between the gas refiner and at least one of the first film formation chamber and the second film formation chamber is less than or equal to 5 m.

21. A film formation method comprising the steps of:
introducing a substrate into a film formation chamber having a leakage rate less than or equal to 1×10⁻¹⁰ Pa·m³/sec and being evacuated to a vacuum level;
introducing a film formation gas having a purity greater than or equal to 99.999999% into the film formation chamber after the substrate is introduced into the film formation chamber; and
sputtering a target using the film formation gas to form a film over the substrate.

22. A film formation method comprising the steps of:
introducing a substrate into a substrate heating chamber evacuated to a vacuum level;
subjecting the substrate to heat treatment at a temperature greater than or equal to 250° C. and less than a strain point of the substrate in an inert atmosphere, a reduced-pressure atmosphere, or a dry air atmosphere after the substrate is introduced into the substrate heating chamber;
introducing the substrate subjected to the heat treatment into a film formation chamber having a leakage rate less than or equal to 1×10⁻¹⁰ Pa·m³/sec and being evacuated to a vacuum level without exposure to air;
introducing a film formation gas having a purity greater than or equal to 99.999999% into the film formation chamber after the substrate is introduced into the film formation chamber, and
sputtering a target using the film formation gas to form a filmover the substrate.

23. A film formation method comprising the steps of:
introducing a substrate into a substrate heating chamber evacuated to a vacuum level;
subjecting the substrate to heat treatment at a temperature greater than or equal to 250° C. and less than a strain point of the substrate in an inert atmosphere, a reduced-pressure atmosphere, or a dry air atmosphere after the substrate is introduced into the substrate heating chamber;
introducing the substrate subjected to the heat treatment into a first film formation chamber having a leakage rate less than or equal to 1×10⁻¹⁰ Pa·m³/sec and being evacuated to a vacuum level without exposure to air;
introducing a first film formation gas having a purity greater than or equal to 99.999999% into the first film formation chamber after the substrate is introduced into the first film formation chamber;
sputtering a first target using the first film formation gas to form an insulating film over the substrate;
introducing the substrate provided with the insulating film into a second film formation chamber having a leakage rate less than or equal to 1×10⁻¹⁰ Pa·m³/sec and being evacuated to a vacuum level without exposure to air;
introducing a second film formation gas having a purity greater than or equal to 99.999999% into the second film formation chamber without exposure to air after the substrate is introduced into the second film formation chamber; and
sputtering a second target using the second film formation gas to form an oxide semiconductor film over the insulating film.

24. A film formation method comprising the steps of:
introducing a substrate into a plasma treatment chamber evacuated to a vacuum level;
subjecting the substrate to plasma treatment after the substrate is introduced into the plasma treatment chamber;
introducing the substrate subjected to the plasma treatment into a first film formation chamber having a leakage rate less than or equal to 1×10⁻¹⁰ Pa·m³/sec and being evacuated to a vacuum level without exposure to air;
introducing a first film formation gas having a purity greater than or equal to 99.999999% into the first film formation chamber after the substrate is introduced into the first film formation chamber;
sputtering a first target using the first film formation gas to form an insulating film over the substrate;
introducing the substrate provided with the insulating film into a second film formation chamber having a leakage rate less than or equal to 1×10⁻¹⁰ Pa·m³/sec and being evacuated to a vacuum level without exposure to air;
introducing a second film formation gas having a purity greater than or equal to 99.999999% into the second film formation chamber after the substrate is introduced into the second film formation chamber; and
sputtering a second target using the second film formation gas to form an oxide semiconductor film over the insulating film.

25. The film formation method according to claim 23,
wherein a substrate temperature is greater than or equal to 100° C. and less than or equal to 400° C. when the oxide semiconductor film is formed.

26. The film formation method according to claim 24,
wherein a substrate temperature is greater than or equal to 100° C. and less than or equal to 400° C. when the oxide semiconductor film is formed.

27. The film formation method according to claim 23,
wherein a substrate temperature is greater than or equal to 50° C. and less than or equal to 450° C. when the oxide semiconductor film is formed.

28. The film formation method according to claim 24,
wherein a substrate temperature is greater than or equal to 50° C. and less than or equal to 450° C. when the oxide semiconductor film is formed.
